(19) United States
(12) Patent Application Publication
(10) Pub. No.: US 2015/0091645 A1
(43) Pub. Date: Apr. 2, 2015

(54) ENVELOPE TRACKING POWER TRANSMITTER USING COMMON-GATE VOLTAGE MODULATION LINEARIZER

(71) Applicant: KOREA ADVANCED INSTITUTE OF SCIENCE AND TECHNOLOG Y, Daejeon (KR)

(72) Inventors: Chul Soon Park, Daejeon (KR); Woo Young Kim, Daejeon (KR); Inn Yeal Oh, Daejeon (KR); Joo Young Jang, Daejeon (KR); Hyuk Su Son, Daejeon (KR)

(21) Appl. No.: 14/500,489

(22) Filed: Sep. 29, 2014

(30) Foreign Application Priority Data
Oct. 1, 2013 (KR) 10-2013-0117154

(51) Int. Cl. H03F 1/02; H03F 3/193; H03F 3/45; H03F 3/217

(52) U.S. Cl. CPC H03F 1/0222; H03F 3/2178; H03F 3/193; H03F 3/45179; H03F 2200/451; H03F 2200/102; H03F 2203/211; H03F 2203/45031
USPC 330/251; 330/260

(57) ABSTRACT

An envelope tracking power transmitter includes an envelope amplifier, a common-gate power modulation linearizer and a power amplifier. The envelope amplifier may receive a first envelope voltage to generate a power supply voltage that is amplified in proportion to change of the first envelope voltage. The common-gate power modulation linearizer may receive a second envelope voltage to amplify the second envelope voltage according to change of the second envelop voltage. The power amplifier may receive a first output of the envelope amplifier as a power supply voltage and a drain bias voltage, may receive a second output of the common-gate power modulation linearizer as a common gate bias voltage, and may amplify a radio frequency (RF) input signal to provide a RF output signal by maintaining an output capacitance according to an envelope of the RF input signal.

### CROSS-REFERENCE TO RELATED APPLICATION

This application claims priority under 35 U.S.C. §119 to Korean Patent Application No. 10-2013-0117154, filed on Oct. 1, 2013, in the Korean Intellectual Property Office (KIPO), the contents of which are herein incorporated by reference in their entirety.

### BACKGROUND

1. Technical Field

Example embodiments relate generally to envelope tracking power transmitters and more particularly to envelope tracking power transmitters using common-gate voltage modulation linearizer.

2. Description of the Related Art

Conventional transmitters use modulation schemes such as quadrature amplitude modulation (QAM) scheme or orthogonal frequency division multiplexing (OFDM) scheme for increasing efficiency of bandwidth. Since modulated signals have non-constant envelope, peak-to-average power ratio (PAPR) of the modulated signals is increased. A power amplifier in the transmitter may maintain linearity of a signal by operating in a back-off area to an extent of the PAPR at a maximum output power, however, an output is rapidly decreased in the back-off area to degrade overall efficiency of the power amplifier. Therefore, battery lifetime may be also decreased.

For increasing efficiency of the transmitter, schemes such as envelope elimination and restoration (EER) scheme or envelope tracking (ET) scheme have been suggested. In the EER scheme, envelope information and phase information are recombined in the power amplifier of the transmitter. The envelope information may be generated by modulating a power supply voltage in an envelope amplifier and phase modulation is provided to an input of the amplifier. In the ET scheme, efficiency may be increased by tracking envelope of a power supply voltage of the power amplifier and changing the tracked envelop to minimize additional power loss. When the power amplifier of the transmitter based on the changed power supply voltage, linearity of an output signal may be degraded due to non-linearity of a transistor in the power amplifier. That is, amplitude-to-amplitude (AM-to-AM) and amplitude-to-phase (AM-to-PM) of the power amplifier may be degraded. Therefore, adjacent channel interference (ACLR) of spectrum of the output signal may be decreased. The non-linearity is mainly due to non-linear change of capacitance of an output stage according to change of the power supply voltage.

For overcoming the non-linearity, digital pre-distortion (DPD) scheme is used in which a linearized input signal is generated by comparing fed-back input signal with the input signal. As for base stations, for implementing the DPD scheme, additional feed-back circuits are required and implementation of real-time feed-back circuit that reprocesses signals in digital domain and outputs the processed signal is not efficient. In addition, for increasing efficiency, envelope tracking power transmitters have been developed, however, the envelope tracking power transmitters are difficult to be integrated with other circuitry of the transmitter because the envelope tracking power transmitters use hetero junction bipolar transistor (HBT) compound semiconductors and SiGe BiCMOS semiconductors.

### SUMMARY

Some example embodiments provide an envelope tracking power transmitter capable of maintaining output capacitance.

According to example embodiments, an envelope tracking power transmitter includes an envelope amplifier, a common-gate power modulation linearizer and a power amplifier. The envelope amplifier may receive a first envelope voltage to generate a power supply voltage that is amplified in proportion to change of the first envelope voltage. The common-gate power modulation linearizer may receive a second envelope voltage to amplify the second envelope voltage according to change of the second envelop voltage. The power amplifier may receive a first output of the envelope amplifier as a power supply voltage and a drain bias voltage, may receive a second output of the common-gate power modulation linearizer as a common gate bias voltage, and may amplify a radio frequency (RF) input signal to provide a RF output signal by maintaining an output capacitance according to an envelope of the RF input signal.

In example embodiments, the power amplifier may include a driving amplifier, a plurality of differential amplifiers and a transmission line transformer. The driving amplifier may receive the RF input signal to drive the RF input signal. The plurality of differential amplifiers may receive the second output of the common-gate power modulation linearizer as the common gate bias voltage, and may receive an output of the driving amplifier as differential input signals to amplify the differential input signals. The transmission line transformer may receive the first output of the envelope amplifier as a direct current power supply voltage and may receive differential output signals of the differential amplifiers to transfer an output power.

The driving amplifier may provide a first output signal and a second output signal by driving the RF input signal.

The plurality of differential amplifiers may include a first different amplifier and a second differential amplifier.

The first differential amplifier may include a first n-channel metal oxide semiconductor (NMOS) transistor that has a gate receiving a first output signal of the driving amplifier and a source coupled to a ground voltage, a second NMOS transistor that has a gate receiving a second output signal of the driving amplifier and a source coupled to the ground voltage, a third NMOS transistor that has a gate receiving the common gate bias voltage, a source coupled to a drain of the first NMOS transistor and a drain coupled to the transmission line transformer and a fourth NMOS transistor that has a gate receiving the common gate bias voltage, a source coupled to a drain of the second NMOS transistor and a drain coupled to the transmission line transformer.

The second differential amplifier may include a first NMOS transistor that has a gate receiving a first output signal of the driving amplifier and a source coupled to a ground voltage, a second NMOS transistor that has a gate receiving a second output signal of the driving amplifier and a source coupled to the ground voltage, a third NMOS transistor that has a gate receiving the common gate bias voltage, a source coupled to a drain of the first NMOS transistor and a drain coupled to the transmission line transformer and a fourth NMOS transistor that has a gate receiving the common gate bias voltage, a source coupled to a drain of the second NMOS transistor and a drain coupled to the transmission line transformer.

In example embodiments, the envelope amplifier may include a linear amplifying stage and a double switching amplifying stage. The linear amplifying stage may receive the first envelope voltage to provide the power supply voltage that is amplified in proportion to the change of the first envelope voltage. The double switching amplifying stage may include different type double switches. The double switching amplifying stage may selectively connect the different type double switches to provide the power amplifier with the power supply voltage including envelope information of the RF input signal.

In example embodiments, the common-gate power modulation linearizer that receives the second envelope voltage to provide the second output.

Accordingly, the envelope tracking power transmitter may maintain output capacitance by increasing the common gate bias voltage applied to gates of the common-gate transistors and may improve AM-to-AM characteristic and AM-to-PM characteristic.

### BRIEF DESCRIPTION OF THE DRAWINGS

Illustrative, non-limiting example embodiments will be more clearly understood from the following detailed description taken in conjunction with the accompanying drawings.

FIG. 1 is a circuit diagram illustrating an envelope tracking power transmitter according to example embodiments.

FIG. 2 is a graph illustrating output capacitance of the power amplifier according to the power supply voltage.

FIG. 3 is a graph illustrating a relationship of a normalized input amplitude, a normalized output amplitude and an output phase.

FIG. 4A is an output spectrum of wideband code division multiple access signal of 3.84 MHz.

FIG. 4B is an output spectrum of long-term evolution signal of 5 MHz.

FIG. 5 is a graph illustrating power added efficiency PAE and adjacent channel interference performance according to output power.

FIG. 6 is a photo illustrating the envelope tracking power transmitter chip designed using 0.18 um CMOS process.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

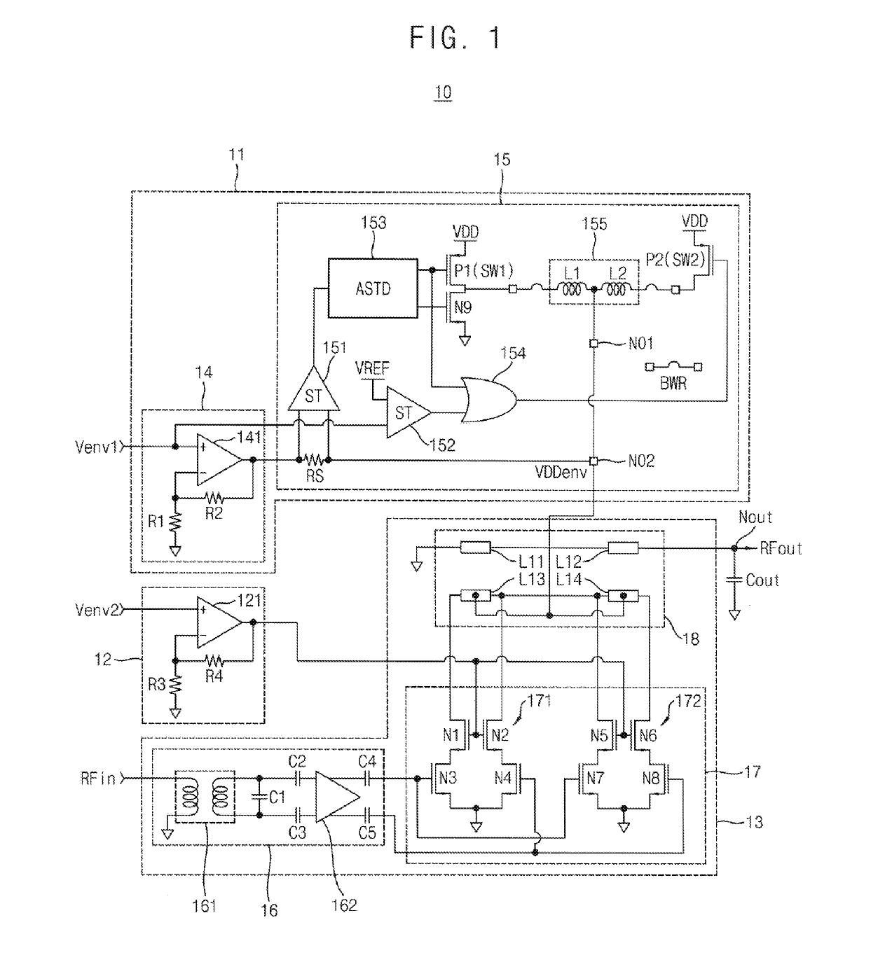

FIG. 1 is a circuit diagram illustrating an envelope tracking power transmitter according to example embodiments.

Referring to FIG. 1, an envelope tracking power transmitter 10 includes an envelope amplifier 11, a common-gate power modulation linearizer 12 and a power amplifier 13.

The envelope amplifier 11 may receive a first envelope voltage Venv1 and generate a power supply voltage which is amplified in proportional to a change of the first envelope voltage Venv1. The envelope amplifier 11 is an amplifier that changes a power supply voltage applied to the power amplifier 13 according to the envelope and the envelop amplifier 11 may include a linear amplifying stage 14 for linearity and a double switching amplifying stage 15 for high efficiency.

The linear amplifying stage 14 may include an operational amplifier 141 that receives the first envelope voltage Venv1 and feedback resistors R1 and R2 that are connected to the operational amplifier 141. The operational amplifier 141 has a positive input terminal receiving the first envelope voltage Venv1, a negative terminal connected to the resistor R1 and an output terminal connected to the resistor R2. The resistor R2 is connected to the resistor R1.

The double switching amplifying state 15 may include Schmitt trigger comparators 151 and 152, a sensing resistor Rs, an anti-shoot through driver (ASTD) 153, an OR gate 154, a p-channel metal oxide (PMOS) transistor P1 which operates as a first switch SW1, a n-channel metal oxide semiconductor (NMOS) transistor N9 an off-chip inductor 155 and a PMPS transistor P2 which operates as a second switch SW2. Output of the operational amplifier 141 is coupled to a first terminal of the sensing resistor RS. The Schmitt trigger comparator 151 receives voltages of the first terminal and a second terminal of the sensing resistor Rs. The Schmitt trigger comparator 152 receives the first envelope voltage Venvl and a reference voltage VREF. The ASTD 153 receives output of the Schmitt trigger comparator 151 and drives the PMOS transistor P1 and the NMOS transistor N9. The PMOS transistor P1 and the NMOS transistor N9 are connected in series between a power supply voltage VDD and a ground voltage. The OR gate 154 receives an input to the PMOS transistor P1 and the output of the Schmitt trigger comparator 152. The off-chip inductor 155 including inductors L1 and L2 is coupled to the drains of the PMOS transistor P1 and the NMOS transistor N9 and a drain of the PMOS transistor P2. Output of the OR gate 154 is applied to a gate of the PMOS transistor P2 which has a source coupled to the power supply voltage VDD.

A first node NO1 coupled to the inductors L1 and L2 is coupled to a second node NO2 by a bond wire BWR, and the second terminal of the sensing resistor R2 is coupled to the second node NO2.

The double switching amplifying stage 15 employing different type double switches SW1 and SW2 may obtain higher efficiency than a switching amplifying stage that employs single type switches. The double switching amplifying stage 15 may selectively connect the different type double switches SW1 and SW2 to provide the power amplifier 13 with a power supply voltage VDDenv including envelope information of a radio frequency (RF) input signal RFin.

The power amplifier 13 may include a driving amplifier circuit 16, a differential amplifier circuit 17 including first and second differential amplifiers 171 and 172, and a transmission line transformer 18. The driving amplifier circuit 16 may include a transformer 161, capacitors C1, C2 and C3, a driving amplifier 162 and capacitors C4 and C4. The capacitors C1, C2 and C3 are connected between the transformer 161 and the driving amplifier 162. The capacitors C4 and C5 are connected between the driving amplifier 162 and the plurality of differential amplifiers 17. The transformer 161 receives the RF input signal RFin to provide the transformed RF input signal RFin to the driving amplifier 162. The driving amplifier 162 drives the RF input signal RFin to be provided to the differential amplifiers 17. The one-to-one transmission line transformer 18 includes inductors L11, L12, L13 and L14 and receives output of the envelope amplifier 11, i.e., the power supply voltage VDDenv including the envelope information. The transmission line transformer 18 provides a RF output signal RFout at an output node Nout. Output capacitor Cout is coupled between the output node Nout and the ground voltage.

The differential amplifier circuit 17 includes the first and second differential amplifiers 171 and 172. The first differential amplifier 171 includes NMOS transistors N1, N2, N3 and N4. The second differential amplifier 172 includes NMOS transistors N5, N6, N7 and N8. First output of the driving amplifier 162 is applied to gates of the NMOS transistors N3 and N7. Second output of the driving amplifier 162 is applied to gates of the NMOS transistors N4 and N8. That is, the first and second differential amplifiers 171 and 172 amplify the first and second output of the driving amplifier 162. The power amplifier 13 receives the output VDDenv of the envelope amplifier 11 as a power supply voltage and a drain bias voltage for each of common-gate transistors N1, N2, N5 and N6. In addition, the power amplifier 13 receives the output of the common-gate power modulation linearizer 12 as a common gate bias voltage for each of common-gate transistors N1, N2, N5 and N6. The power amplifier 13 couples the output VDDenv of the envelope amplifier 11 to the RF output RFout by charge sharing scheme using the one-to-one transmission line transformer 18. The one-to-one transmission line transformer 18 receives the output VDDenv of the envelope amplifier 11 as direct current power supply voltage and transmits the RF output signal RFout by receiving the output differential signals of the first and second differential amplifiers 171 and 172 at respective two ends of the inductors L13 and L14.

The common-gate power modulation linearizer 12 may include an operational amplifier 121 that receives a second envelope voltage Venv2 and feedback resistors R3 and R4 that are connected to the operational amplifier 121. The operational amplifier 121 has a positive input terminal receiving the second envelope voltage Venv2, a negative terminal connected to the resistor R3 and an output terminal connected to the resistor R4. The resistor R4 is connected to the resistor R3.

The common-gate power modulation linearizer 12 receives the second envelope voltage Venv2 which is a scaled version of the first envelope voltage Venvl for changing common gate voltage applied to the gates of the common-gate transistors N1, N2, N5 and N6 and amplifies the second envelope voltage Venv2 in proportional to change of the second envelope voltage Venv2. The first envelope voltage Venvl corresponds to an envelope voltage of the RF input signal RFin and the second envelope voltage Venv2 is the scaled version of the first envelope voltage Venv1. Therefore, when the envelope of the RF input signal RFin changes, the first envelope voltage Venv1 and the second envelope voltage Venv2 also change in cooperation with the change of the RF input signal RFin.

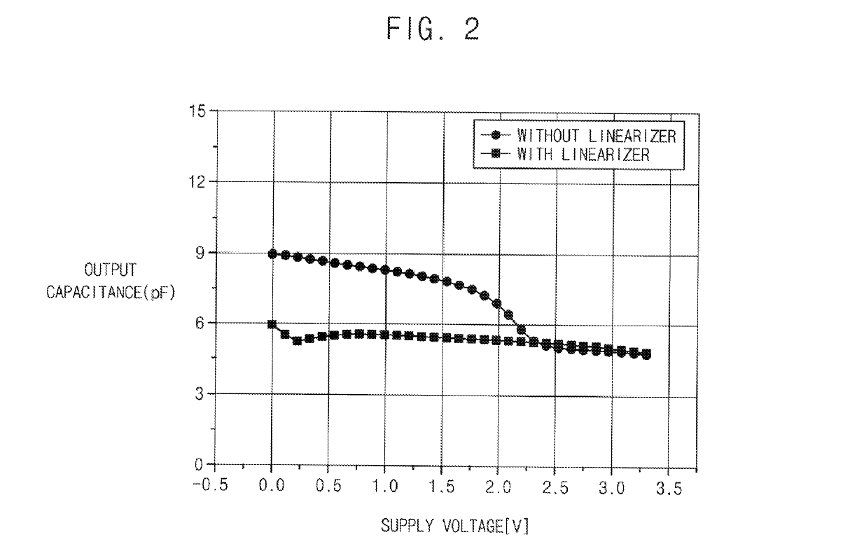

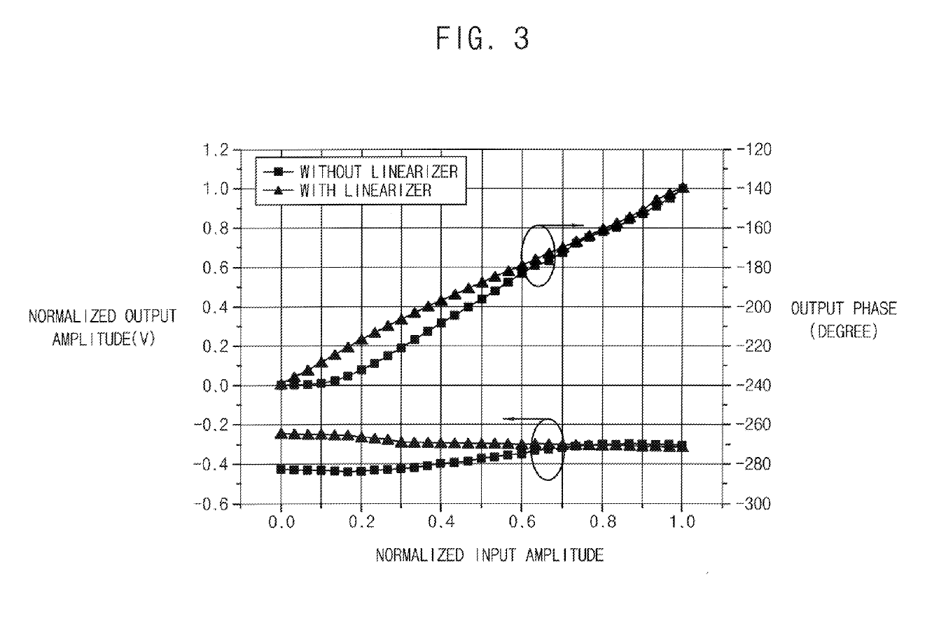

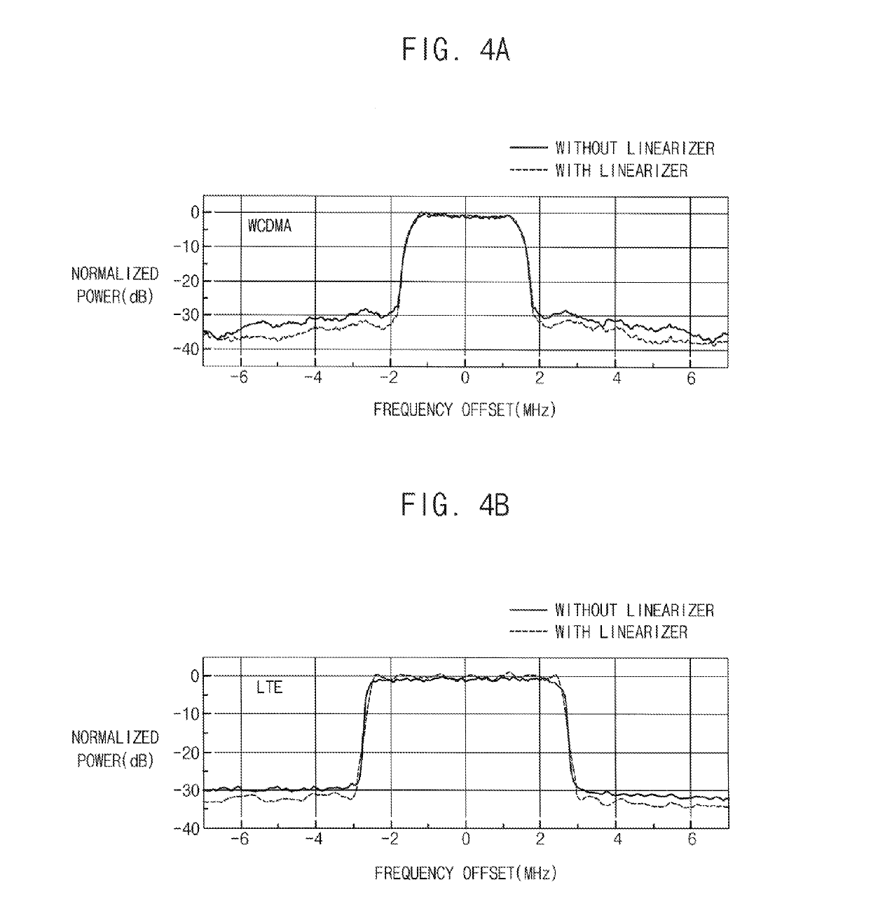

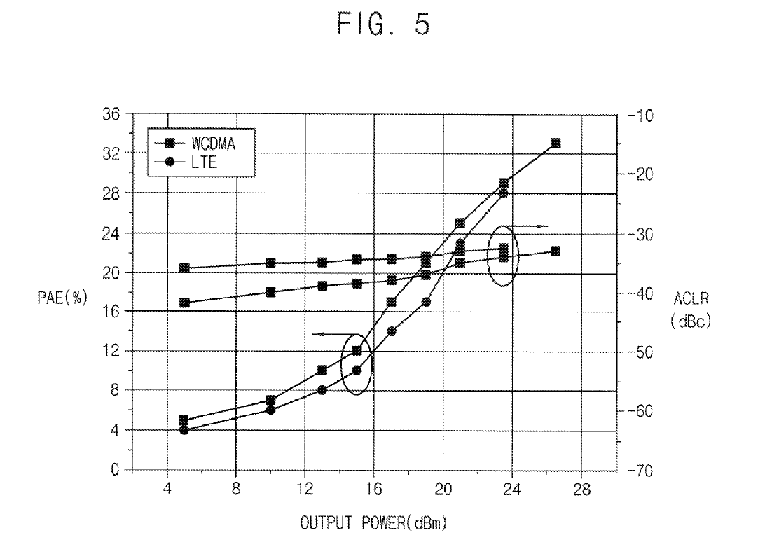

The common-gate power modulation linearizer 12 may modulate the common gate bias voltage for each of common-gate transistors N1, N2, N5 and N6 in the first and second differential amplifiers 171 and 172 by amplifying the second envelope voltage Venv2. The common-gate power modulation linearizer 12 may increase linearity by being integrated in the transmitter using a power supply voltage circuit of a simple operational amplifier without requiring additional feedback circuit and calibration in digital domain. The common-gate power modulation linearizer 12 may reshape the common gate bias voltage for each of common-gate transistors N1, N2, N5 and N6 to have a range from 1[V] to 1.25[V] according to the second envelope voltage Venv2 when the power supply voltage of the power amplifier 13 changes from 0.3[V] to 3.3[V]. Therefore, capacitance of the output node Nout of the power amplifier 13 may be constant with being maintained within 0.3 pF change based on 4.5 pF as illustrated in FIG. 2. Therefore, the AM-to-AM characteristic of the power amplifier 13 may be linearized and the AM-to-PM characteristic of the power amplifier 13 may be improved by 10 degrees at maximum as illustrated in FIG. 3. Accordingly, the ACLR characteristic of the RF output signal RFout is improved by 4.5 dB in wideband code division multiple access (WCDMA) and 3 dB in long-term evolution (LTE) respectively as illustrated in FIGS. 4A and 4B. As for FIGS. 4A, 4B and 5, operating frequency is 1.9 GHz used for WCDMA and LTE systems, output powers are 26 dBm in WCDMA and 24.5 dBm in LTE respectively and efficiencies are about 33% in WCDMA and about 28% in LTE respectively. In this case, ACLRs are about −33dBc in WCDMA and about −32.5 dBc in LTE respectively.

As described above, the envelope tracking power transmitter 10 may maintain output capacitance and may improve non-linearity by increasing the common gate bias voltage applied to gates of the common-gate transistors N1, N2, N5 and N6 included in the power amplifier 13 in cooperation with a power supply voltage applied to the power supply voltage, which is changed according to envelope information of the RF input signal and by maintaining each drain-source voltage of the common-gate transistors N1, N2, N5 and N6 of the first and second differential amplifiers 171 and 172.

FIG. 2 is a graph illustrating output capacitance of the power amplifier according to the power supply voltage.

Referring to FIG. 2, when the common-gate power modulation linearizer 12 is not included in the envelope tracking power transmitter 10, it is noted that output capacitance of the power amplifier 13 changes non-linearly from about 9 pF to about 4.5 pF as the power supply voltage increases. However, when the common-gate power modulation linearizer 12 is included in the envelope tracking power transmitter 10, it is noted that output capacitance of the power amplifier 13 changes linearly within error limit of 0.3 pF around 4 pF as the power supply voltage increases. Therefore, the AM-to-AM characteristic of the power amplifier 13 may be linearized and the AM-to-PM characteristic of the power amplifier 13 may be improved by 10 degrees at maximum as illustrated in FIG. 3. Accordingly, the ACLR characteristic of the RF output signal RFout is improved by 4.5 dB in wideband code division multiple access (WCDMA) and 3 dB in long-term evolution (LTE) respectively as illustrated in FIGS. 4A and 4B.

FIG. 3 is a graph illustrating a relationship of a normalized input amplitude, a normalized output amplitude and an output phase.

Referring to FIG. 3, when the common-gate power modulation linearizer 12 is not included in the envelope tracking power transmitter 10, it is noted that non-linearity is increased when the normalized input amplitude is low and phase variance is about 20 degrees at maximum. However, when the common-gate power modulation linearizer 12 is included in the envelope tracking power transmitter 10, the normalized output amplitude is linearly proportional to the normalized input amplitude and the phase variance is about 10 degrees at maximum.

FIG. 4A is an output spectrum of wideband code division multiple access (WCDMA) signal of 3.84 MHz.

FIG. 4B is an output spectrum of long-term evolution (LTE) signal of 5 MHz.

In FIG. 4A, the WCDMA signal has about 3.5 dB PAPR and in FIG. 4B, the LTE signal has about 7.5 dB PAPR.

Referring to FIGS. 4A and 4B, when the common-gate power modulation linearizer 12 is included in the envelope tracking power transmitter 10, ACLR performances are improved by about 4.5 dB in case of the WCDMA signal and by about 3 dB in case of the LTE signal, respectively. In addition, average output powers are about 26 dBm in case of the WCDMA signal and about 23.5 dBm in case of the LTE signal, respectively.

FIG. 5 is a graph illustrating power added efficiency PAE and adjacent channel interference (ACLR) performance according to output power.

Referring to FIG. 5, it is noted that the average output powers are about 26 dBm at maximum and the PAE is about 33% in case of the WCDMA signal and the average output powers are about 23.5 dBm at maximum and the PAE is about 28% in case of the LTE signal.

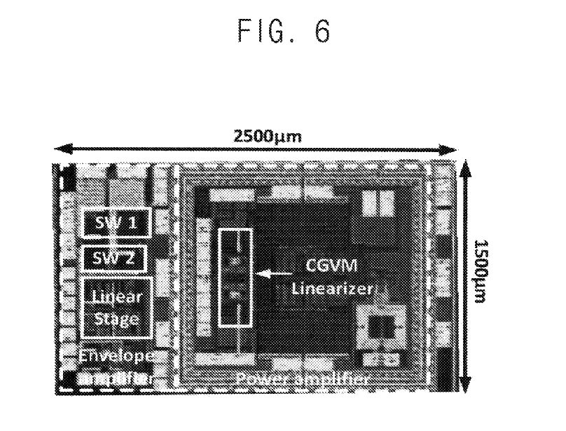

FIG. 6 is a photo illustrating the envelope tracking power transmitter chip designed using 0.18 um CMOS process.

Referring to FIG. 6, an input matching circuit and an output matching circuit are implemented in one chip, and the envelope tracking power transmitter chip is reduced to have a size of 2.5 mm multiplied by 1.5 mm by integrating the envelope amplifier 11, the common-gate power modulation linearizer 12 and the power amplifier 13 into one chip.

Table below describes performances of conventional envelope tracking power transmitters and the envelope tracking power transmitter according to present disclosure.

TABLE

| | | | Avg. | | Signal | | Output | |
|---|---|---|---|---|---|---|---|---|
| | Freq. | VDD | Pout | Overall | BW | | Matching | |
| | (GHz) | (V) | (dBm) | PAE | (MHz) | Mod. | Network | Lin. |
| First | 1.88 | 3.3 | 29 | 46 | 3.84 | WCDMA | Off-chip | No |
| Conv. | | | 23.9 | 34.3 | 5 | LTE | | |
| Second | 1.9 | 3.6 | 24.6 | 26 | 5 | LTE | On-chip | No |
| Conv. | | | | | | | | |
| Present | 1.9 | 3.3 | 26 | 33 | 3.84 | WCDMA | On-chip | Yes |
| disclosure | | | | | | | | |

In the table, the first conventional envelope tracking power transmitter is implemented using a HBT compound semiconductor process and additional matching circuit is implemented on a printed circuit board (PCB). The second conventional envelope tracking power transmitter is implemented using a SiGe BiCMOS process and an on-chip matching circuit is included. The present disclosure implements the envelope tracking power transmitter 10 and the common-gate power modulation linearizer 12 which are on-chipped.

What is claimed is:

1. An envelope tracking power transmitter comprising:
an envelope amplifier configured to receive a first envelope voltage to generate a power supply voltage that is amplified in proportion to change of the first envelope voltage;
a common gate power modulation linearizer configured to receive a second envelope voltage to amplify the second envelope voltage according to change of the second envelop voltage; and
a power amplifier configured to receive a first output of the envelope amplifier as a power supply voltage and a drain bias voltage, configured to receive a second output of the common-gate power modulation linearizer as a common gate bias voltage, and configured to amplify a radio frequency (RF) input signal to provide a RF output signal by maintaining an output capacitance according to an envelope of the RF input signal.

2. The envelope tracking power transmitter of claim 1, wherein the power amplifier comprises:
a driving amplifier configured to receive the RF input signal to drive the RF input signal;
a plurality of differential amplifiers configured to receive the second output of the common-gate power modulation linearizer as the common gate bias voltage, and configured to receive an output of the driving amplifier as differential input signals to amplify the differential input signals; and
a transmission line transformer configured to receive the first output of the envelope amplifier as a direct current power supply voltage and configured to receive differential output signals of the differential amplifiers to transfer an output power.

3. The envelope tracking power transmitter of claim 2, wherein the driving amplifier provides a first output signal and a second output signal by driving the RF input signal.

4. The envelope tracking power transmitter of claim 2, wherein the plurality of differential amplifiers include a first different amplifier and a second differential amplifier.

5. The envelope tracking power transmitter of claim 4, wherein the first differential amplifier comprises:
a first n-channel metal oxide semiconductor (NMOS) transistor that has a gate receiving a first output signal of the driving amplifier and a source coupled to a ground voltage;
a second NMOS transistor that has a gate receiving a second output signal of the driving amplifier and a source coupled to the ground voltage;
a third NMOS transistor that has a gate receiving the common gate bias voltage, a source coupled to a drain of the first NMOS transistor and a drain coupled to the transmission line transformer; and
a fourth NMOS transistor that has a gate receiving the common gate bias voltage, a source coupled to a drain of the second NMOS transistor and a drain coupled to the transmission line transformer.

6. The envelope tracking power transmitter of claim 4, wherein the second differential amplifier comprises:
a first n-channel metal oxide semiconductor (NMOS) transistor that has a gate receiving a first output signal of the driving amplifier and a source coupled to a ground voltage;
a second NMOS transistor that has a gate receiving a second output signal of the driving amplifier and a source coupled to the ground voltage;
a third NMOS transistor that has a gate receiving the common gate bias voltage, a source coupled to a drain of the first NMOS transistor and a drain coupled to the transmission line transformer; and
a fourth NMOS transistor that has a gate receiving the common gate bias voltage, a source coupled to a drain of the second NMOS transistor and a drain coupled to the transmission line transformer.

7. The envelope tracking power transmitter of claim 1, wherein the envelope amplifier comprises:
a linear amplifying stage configured to receive the first envelope voltage to provide the power supply voltage that is amplified in proportion to the change of the first envelope voltage; and
a double switching amplifying stage including different type double switches, the double switching amplifying stage configured to selectively connect the different type double switches to provide the power amplifier with the power supply voltage including envelope information of the RF input signal.

8. The envelope tracking power transmitter of claim 1, wherein the common-gate power modulation linearizer comprises:
an operational amplifier configured to receive the second envelope voltage to provide the second output.
